(19) United States
(12) Patent Application Publication
(10) Pub. No.: US 2026/0120779 A1
(43) Pub. Date: Apr. 30, 2026

(54) PROGRAM REFRESH FOR NON-VOLATILE MEMORY CELLS

(71) Applicant: Silicon Storage Technology, Inc., San Jose, CA (US)

(72) Inventors: Stefano Surico, Milan (IT); SIMONE BARTOLI, Lecco (IT); STEFANO SIVERO, Comun Nuovo BG (IT); GUISEPPE MOIOLI, Alzano Lombardo (BG) (IT); XIAN Liu, Sunnyvale, CA (US); THAI LE, Ho Chi Minh (VN); AN VO, Ho Chi Minh (VN)

(21) Appl. No.: 19/019,224

(22) Filed: Jan. 13, 2025

Related U.S. Application Data
(60) Provisional application No. 63/714,813, filed on Oct. 31, 2024.

(51) Int. Cl. G11C 16/34; G11C 16/26

(52) U.S. Cl. CPC G11C 16/3431; G11C 16/26; G11C 16/3459

(57) ABSTRACT

A programming method for a semiconductor device that includes programming a first memory cell to a first program state that is associated with a first program verify voltage and a first reference voltage such that the first memory cell has a first threshold voltage that meets or exceeds the first program verify voltage. The first program verify voltage is greater than the first reference voltage. A first read operation is performed which determines the first threshold voltage of the first memory cell has drifted down to between the first program verify voltage and the first reference voltage. In response to this determination, the first memory cell is programmed to increase the first threshold voltage of the first memory cell to meet or exceed the first program verify voltage.

### RELATED APPLICATIONS

This application claims the benefit of U.S. Provisional Application No. 63/714,813, filed Oct. 31, 2024, and which is incorporated herein by reference.

### FIELD OF THE INVENTION

The present invention relates to non-volatile memory cells of semiconductor devices, and more particularly to a technique of programming memory cells.

### BACKGROUND OF THE INVENTION

Split-gate non-volatile memory semiconductor devices are well known in the art. See for example U.S. Pat. No. 7,868,375, which discloses a four-gate memory cell configuration, and which is incorporated herein by reference for all purposes. Specifically, FIG. 1 of the present disclosure illustrates a pair of split gate non-volatile memory cells 10 each with spaced apart source and drain regions 14/16 formed in a semiconductor substrate 12 (e.g., silicon). The source region 14 can be referred to as a source line SL (because it commonly is connected to other source regions for other non-volatile memory cells 10 in the same row or column), and the drain region 16 is commonly connected to a bit line. A channel region 18 of the semiconductor substrate 12 extends between the source/drain regions 14/16. A floating gate 20 is disposed over (i.e., vertically over and laterally overlapping) and insulated from (and directly controls the conductivity of) a first portion of the channel region 18 (and partially over, and insulated from, the source region 14). A control gate 22 is disposed over, and insulated from, the floating gate 20. A select gate 24 (also referred to as a word line gate) is disposed over, and insulated from, and directly controls the conductivity of, a second portion of the channel region 18. An erase gate 26 is disposed over and insulated from the source region 14 and is laterally adjacent to the floating gate 20. The erase gate 26 can include a notch that faces an edge of the floating gate 20.

A plurality of such memory cells 10 can be arranged in rows and columns to form a memory cell array, as illustrated in FIG. 2. While FIG. 1 only shows a pair of memory cells (sharing a common source region 14 and erase gate 26), the memory cell pairs can be placed end to end to form a column of memory cells 10 (where the memory cell pairs can share a common drain region 16). While only two such columns are shown in FIG. 2, there can be many such columns. Each column can include a bit line 16a electrically connecting together all the drain regions 16 in the column. Each row of memory cells 10 can include a control gate line 22a electrically connecting together all the control gates 22 in the row of memory cells 10. For example, all the control gates 22 in each row of memory cells 10 can be formed as a continuous line of conductive material, where a portion of the continuous line passing through any given memory cell 10 serves as its control gate 22. Each row of memory cells 10 can include a select gate line 24a electrically connecting together all the select gates 24 in the row of memory cells 10. For example, all the select gates 24 in each row of memory cells 10 can be formed as a continuous line of conductive material, where a portion of the continuous line passing through any given memory cell 10 serves as its select gate 24. Each row of memory cell pairs can include an erase gate line 26a electrically connecting together all the erase gates 26 in the row of memory cell pairs. For example, all the erase gates 26 in each row of memory cell pairs can be formed as a continuous line of conductive material, where a portion of the continuous line passing through any given memory cell pair serves as its erase gate 26. Finally, each row of memory cell pairs can include a source line 14a electrically connecting together all the source regions 14 in the row of memory cell pairs. For example, all the source regions 14 in each row of memory cell pairs can be formed as a continuous line of conductive diffusion in the substrate 12, where a portion of the continuous line passing through any given memory cell pair serves as its source region 14.

Various combinations of voltages are applied to the control gate 22, select gate 24, erase gate 26 and source and drain regions 14/16, to program the split gate non-volatile memory cell 10 (i.e., inject electrons onto the floating gate 20), to erase the split gate non-volatile memory cell 10 (i.e., remove electrons from the floating gate 20), and to read the split gate non-volatile memory cell 10 (i.e., measure or detect the conductivity of the channel region 18, by for example measuring or detecting a read current through the channel region 18, to determine the programming state of the floating gate 20).

Split gate non-volatile memory cell 10 can be operated in a digital manner, where the split gate non-volatile memory cell 10 is set to one of only two possible states: a programmed state and an erased state. The split gate non-volatile memory cell 10 is erased by placing a high positive voltage on the erase gate 26, and optionally a negative voltage on the control gate 22, to induce tunneling of electrons from the floating gate 20 to the erase gate 26 (leaving the floating gate 20 in a more positively charged state—the erased state). Split gate non-volatile memory cell 10 can be programmed by placing positive voltages on the control gate 22, erase gate 26, select gate 24 and source region 14, and a current on drain region 16. Electrons will then flow along the channel region 18 from the drain region 16 toward the source region 14, with electrons becoming accelerated and heated whereby some of them are injected onto the floating gate 20 by hot-electron injection (leaving the floating gate 20 in a more negatively charged state—the programmed state).

One technique to program the memory cells 10 is sequential programming, which involves applying the programming voltages as a series of pulses, with each pulse of programming voltages injecting more electrons onto the floating gate thus increasing the program state of the memory cell 10 with each pulse, until the desired programming state is achieved (i.e., until the desired read current for the desired programming state is achieved). With sequential programming, there can be intervening read operations between the programming pulses (referred to herein as read verify) to determine if the desired programming state has been achieved by the last applied programming pulse (in which case programming ceases) or has not been achieved (in which case programming continues with one or more programming pulses). For example, each desired program state can be associated with a target read current Irtarget (i.e., the desired and therefore target current through the channel region 18 during a read operation that is associated with the desired program state). Additionally, each program state can be associated with a target threshold voltage Vth (i.e., the desired and therefore target minimum voltage applied to a gate or region during a read operation that through capacitive coupling is sufficient to cause enough current through the channel region 18 to meet a specific read operation threshold.) The higher the program state (i.e., the more electrons on the floating gate), the lower the read current Ir and the higher the threshold voltage Vth. Therefore, the read current Ir will drop, and the threshold voltage Vth will rise, after each programming pulse. Once a target read current Irtarget or target threshold voltage Vth is reached (reflecting the desired program state), programming for that memory cell 10 ceases.

If the same set of program voltages are applied during each pulse in sequential programming, the programming amount drops pulse to pulse, because as the floating gate becomes more negatively charged with each pulse, fewer electrons are injected onto the floating gate if the parameters of the programming pulses (applied voltages, supplied current, duration) remain constant. Therefore, when a memory cell 10 is determined to have not reached its desired programming state after any given pulse, one or more of the programming parameters can be stepped up to a higher value in the next pulse, to compensate for the dropping pulse-to-pulse programming amount that would otherwise occur. For example, for the memory cell 10 of FIG. 1, programming parameters that can be stepped up from one programming pulse to the next programming pulse can include increases in one or more of the following: voltage applied to the control gate 22, voltage applied to the erase gate 26, voltage applied to the source region 14, current supplied to the drain region 16, and duration of the programming pulse.

Split gate non-volatile memory cell 10 can be read by placing positive voltages on the select gate 24 (turning on the portion of channel region 18 under the select gate 24 by making it conductive) and drain region 16 (and optionally on the erase gate 26 and the control gate 22), and sensing current flow through the channel region 18. If the floating gate is positively charged (i.e. split gate non-volatile memory cell 10 is erased), the split gate non-volatile memory cell 10 will turn on because the both portions of the channel region 18 are conductive due to the lack of electrons on the floating gate 20, and electrical current will flow from drain region 16 to source region 14 (i.e. the split gate non-volatile memory cell 10 is sensed to be in its erased “1” state based on sensed current flow). If the floating gate 20 is negatively charged (i.e. split gate non-volatile memory cell 10 is programmed), the portion of channel region 18 under the floating gate is turned off (low conductivity), thereby preventing appreciable current flow (i.e., the split gate non-volatile memory cell 10 is sensed to be in its programmed “0” state based on no, or minimal, current flow). Memory cells 10 are considered non-volatile because they maintain their program state even when power is not applied to the semiconductor device. Memory cells 10 can be referred to as split gate non-volatile memory cells because two different gates (floating gate 20 and select gate 24), respectively, directly control the conductivity of two different portions of the channel region 18.

Split gate non-volatile memory cell 10 can alternately be operated in an analog manner where the program state (i.e. the amount of charge, such as the number of electrons, on the floating gate 20) of the split gate-non-volatile memory cell 10 can be incrementally changed anywhere from a fully erased state (minimum number of electrons on the floating gate 20) to a fully programmed state (maximum number of electrons on the floating gate 20), or just a portion of this range. This means the split gate non-volatile memory cell 10 storage is analog, which allows for very precise and individual tuning of each split gate non-volatile memory cell 10 in an array of split gate non-volatile memory cells 10.

Alternatively, the split gate non-volatile memory cell 10 could be operated as an MLC (multilevel cell) where it is configured to be programmed to one of many discrete values (such as 4, 8, 16 or 64 different values). These different values can be referred to as program states. FIGS. 3 and 4 show the program states for a memory cell storing 2 bits (i.e., using four possible program states) as a function of cell current Icell (FIG. 3) or threshold voltage Vth (FIG. 4) during a read operation. The program and erase operations result in a distribution of cell current Icell and threshold voltage Vth for each program state given these operations are not perfectly precise. The fully erased program state 11 provides the highest cell current Icell (as shown in FIG. 3), and the lowest threshold voltage Vth (as shown in FIG. 4) during a read operation. Conversely, the fully programmed state 10 provides the lowest cell current Icell (as shown in FIG. 3), and the highest threshold voltage Vth (as shown in FIG. 4) during a read operation. As used herein, the higher the number of electrons on the floating gate, the higher the program state. Therefore, the fully programmed state 10 is the highest program state, and the fully erased program state 11 is the lowest program state.

Split gate non-volatile memory cells with fewer gates are also known. For example, FIG. 5 illustrates known split gate non-volatile memory cells 10 that are the same as that of FIG. 1, except the control gates 22 are omitted. See for example U.S. Pat. No. 7,315,056, which is incorporated herein by reference for all purposes. Voltage coupling to the floating gate 20 provided by the control gate 22 of the split gate non-volatile memory cell of FIG. 1 is provided instead by the erase gate 26 and source region 14 of the split gate non-volatile memory cell 10 in FIG. 5. FIG. 6 illustrates an example layout of an array of the split gate non-volatile memory cells 10 of FIG. 5.

As another example, FIG. 7 illustrates known split gate non-volatile memory cells that are similar to that of FIG. 1, except the control gates 22 and the erase gates 26 are omitted. See for example U.S. Pat. No. 5,029,130, which is incorporated herein by reference for all purposes. The erase voltage for the split gate non-volatile memory cell 10 of FIG. 7 is applied to the select gate 24, which has a first portion laterally adjacent the floating gate 20, and a second portion that extends up and over the floating gate 20. FIG. 8 illustrates an example layout of an array of the split gate non-volatile memory cells 10 of FIG. 7.

As yet another example, FIG. 9 illustrates known split gate non-volatile memory cells 10 that are similar to that of FIG. 7, except a conductive block of material 28 is formed in contact with source region 14, to serve as an extended source line. See for example U.S. Pat. No. 6,855,980, which is incorporated herein by reference for all purposes. An example layout for an array of the split gate non-volatile memory cells 10 of FIG. 9 can be the same as that in FIG. 8.

One issue with split gate non-volatile memory cells 10 is charge loss, where after programming, the threshold voltage Vth drops and the read current Icell increases over time. One source of charge loss is leakage of electrons off of the floating gate. Another source of charge loss is electrons trapped in the dielectric materials around the floating gate become detrapped and move away from the floating gate. If the magnitude of charge loss becomes excessive, it can cause a read error by making the memory cell appear to be programmed in the next lower program state during a read operation. There is a need to reduce the number of such read errors when charge loss occurs.

### BRIEF SUMMARY OF THE INVENTION

The aforementioned problems and needs are addressed by a programming method for a semiconductor device that comprises programming a first memory cell to a first program state that is associated with a first program verify voltage and a first reference voltage such that the first memory cell has a first threshold voltage that meets or exceeds the first program verify voltage, wherein the first program verify voltage is greater than the first reference voltage; determining in a first read operation that the first threshold voltage of the first memory cell has drifted down to between the first program verify voltage and the first reference voltage; and in response to the determining in the first read operation, programming the first memory cell to increase the first threshold voltage of the first memory cell to meet or exceed the first program verify voltage.

A semiconductor device comprises a plurality of memory cells formed on a semiconductor substrate, and control circuitry to program a first memory cell of the plurality of memory cells to a first program state that is associated with a first program verify voltage and a first reference voltage such that the first memory cell has a first threshold voltage that meets or exceeds the first program verify voltage, wherein the first program verify voltage is greater than the first reference voltage; determine in a first read operation that the first threshold voltage of the first memory cell has drifted down to between the first program verify voltage and the first reference voltage; and in response to the determination in the first read operation, program the first memory cell to increase the first threshold voltage of the first memory cell to meet or exceed the first program verify voltage.

Other objects and features of the present disclosure will become apparent by a review of the specification, claims and appended figures.

### BRIEF DESCRIPTION OF THE DRAWINGS

FIG. 1 is a cross sectional view of a conventional pair of memory cells.

FIG. 2 is a schematic and layout diagram of a conventional memory cell array of the memory cells of FIG. 1.

FIG. 3 is a diagram illustrating program state distributions as a function of cell current Icell in a read operation.

FIG. 4 is a diagram illustrating program state distributions as a function of threshold voltage Vth in a read operation.

FIG. 5 is a side cross sectional view of a conventional pair of memory cells.

FIG. 6 is a schematic and layout diagram of a conventional memory cell array of the memory cells of FIG. 5.

FIG. 7 is a side cross sectional view of a conventional pair of memory cells.

FIG. 8 is a schematic and layout diagram of a conventional memory cell array of the memory cells of FIG. 7.

FIG. 9 is a side cross sectional view of a conventional pair of memory cells.

FIG. 10 is a diagram illustrating components of a semiconductor device.

FIG. 11 is a diagram illustrating a first example of voltages and target margins associated with various program states.

FIG. 12 is a diagram illustrating charge loss drift and refresh programming for one of the program states of FIG. 11.

FIG. 13 is a diagram illustrating a second example of voltages and target margins associated with various program states.

FIG. 14 is a diagram illustrating charge loss drift and refresh programming for one of the program states of FIG. 13.

FIG. 15 is a diagram illustrating a first example of a refresh operation process flow.

FIG. 16 is a diagram illustrating a second example of a refresh operation process flow.

FIG. 17 is a diagram illustrating a third example of a refresh operation process flow.

FIG. 18 is a diagram illustrating a fourth example of a refresh operation process flow.

FIG. 19 is a diagram illustrating a fifth example of a refresh operation process flow.

FIG. 20 is a diagram illustrating a sixth example of a refresh operation process flow.

FIG. 21 is a diagram illustrating significant charge loss drift and refresh programming for one of the program states of FIG. 11.

FIG. 22 is a diagram illustrating significant charge loss drift and refresh programming for one of the program states of FIG. 13.

FIG. 23 is a diagram illustrating a seventh example of a refresh operation process flow for significant charge loss drift of FIGS. 21-22.

### DETAILED DESCRIPTION OF THE INVENTION

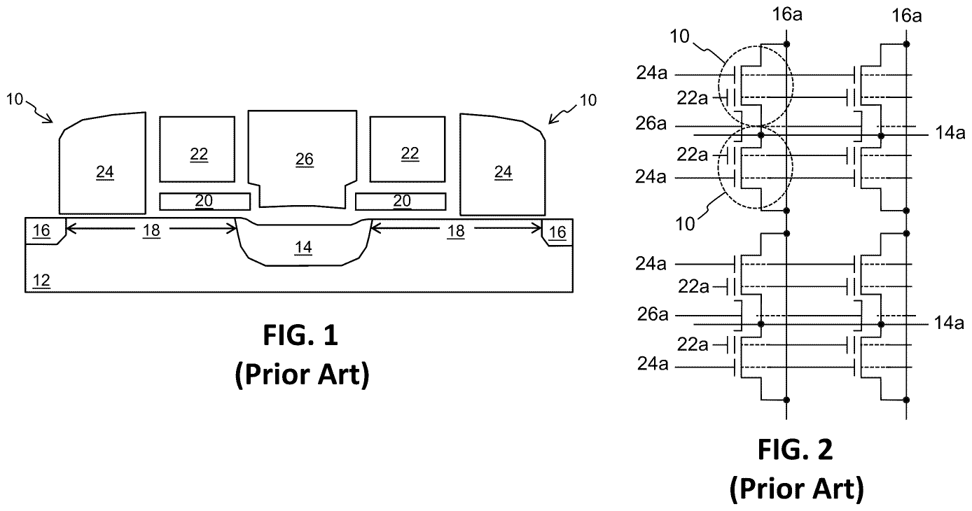

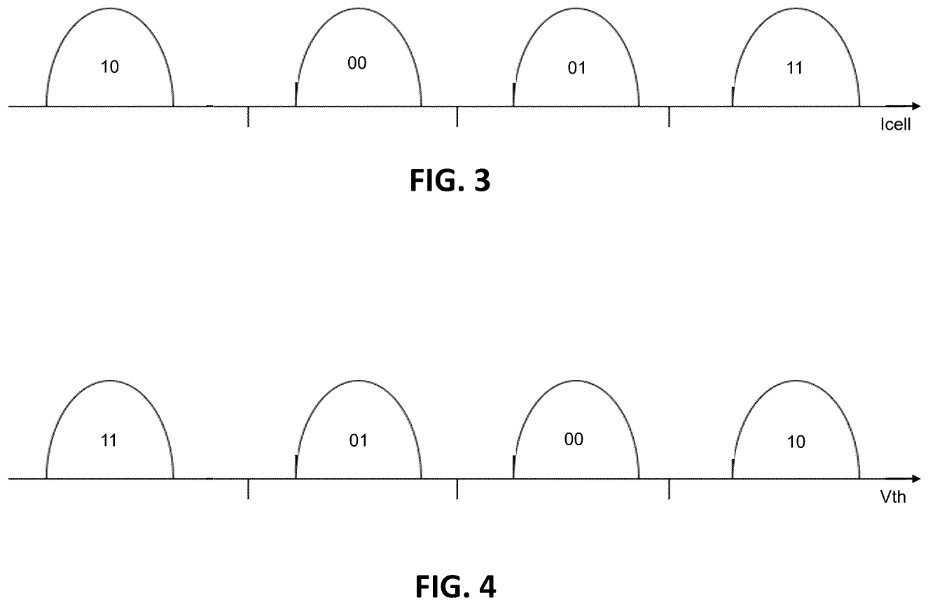

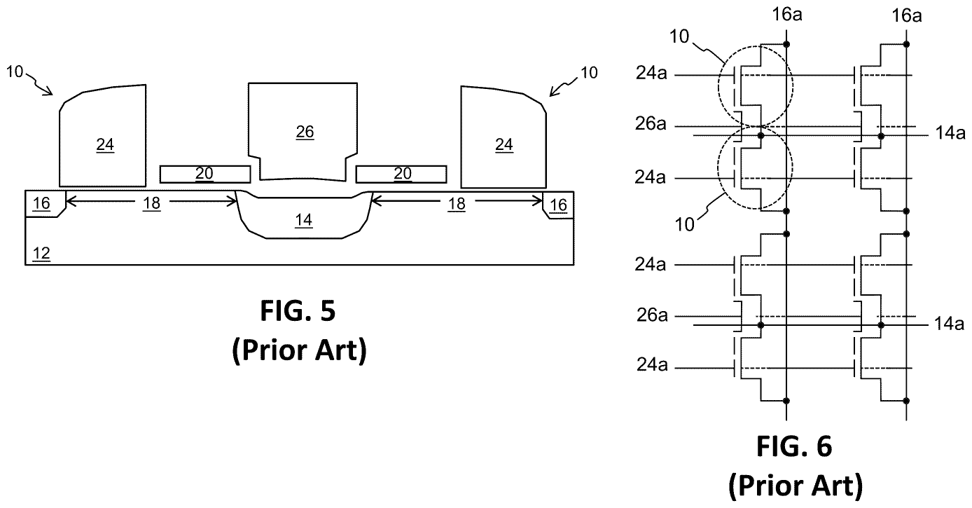

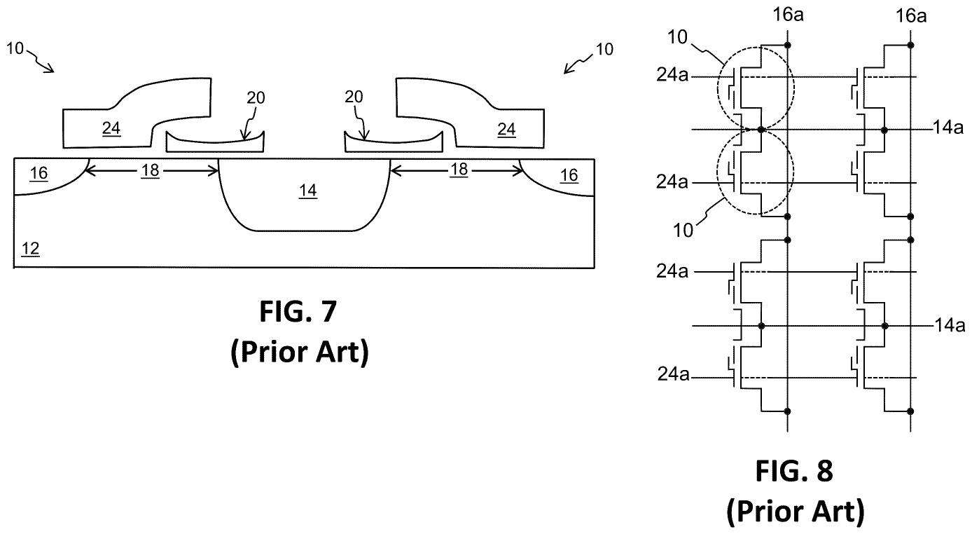

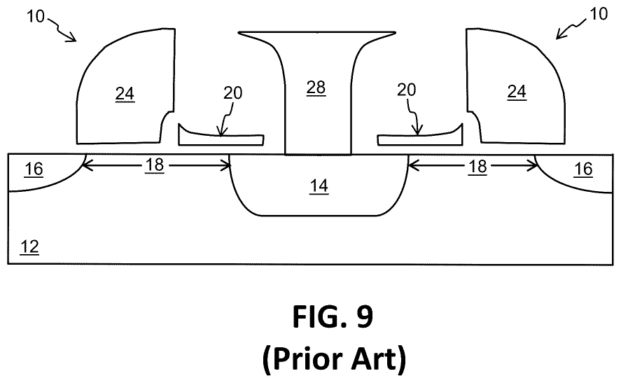

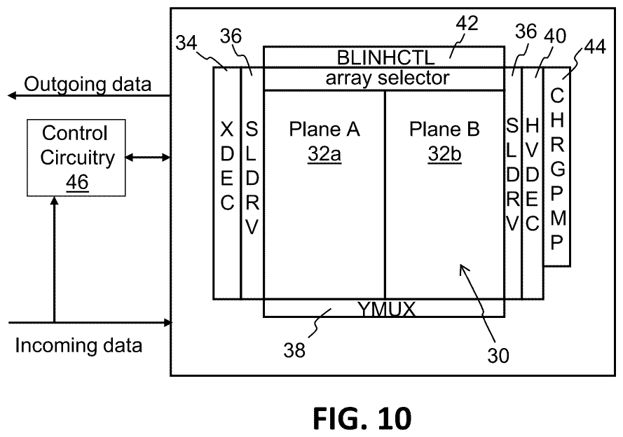

The present examples illustrate memory cell refresh programing methods to address charge loss. The refresh programming methods can be implemented as part of control circuitry 46, which controls the various device elements for a memory array, which can be better understood from the architecture of an example semiconductor device as illustrated in FIG. 10. The semiconductor device includes an array 30 of the split gate memory cells 10, which can be segregated into two separate planes (Plane A 32a and Plane B 32b). The split gate memory cells 10 can be of the type shown in FIG. 1, 5, 7 or 9, arranged in a plurality of rows and columns in the semiconductor substrate 12 as illustrated in FIG. 2, 6 or 8, and thus formed on a single chip. It should be noted however, that the memory cells can be any memory cell that includes a floating gate, including a stacked gate memory cell where the floating gate extends over and controls the entirety of the channel region. Adjacent to the array 30 of split gate memory cells 10 are an address decoder 34 (e.g., XDEC), source line drivers 36 (e.g., SLDRV), a column decoder 38 (e.g., YMUX), a high voltage row decoder 40 (e.g., HVDEC), a bit line controller 42 (e.g., BLINHCTL), and a charge pump 44 (e.g., CHRGPMP), which are used to decode addresses and supply the various voltages to the various gates and regions of the split gate memory cells 10 during read, program, and erase operations for selected split gate memory cells 10 of the array 30, under the control of the control circuitry 46. Column decoder 38 includes a sense amplifier containing circuitry for measuring the currents on the bit lines during a read operation. Control circuitry 46 controls the various device elements to implement each operation (program, erase, read) on selected split gate memory cells 10 of the array 30 as described herein. Control circuitry 46 operates the semiconductor device to program, erase and read the selected split gate memory cells 10 of the array 30. As part of these operations, the control circuitry 46 can be provided with access to incoming data which is user data to be programmed to the selected split gate memory cells 10 of the array 30, along with program, erase and read commands provided on the same or different lines. Data read from the array (i.e., from selected split gate memory cells 10 of the array 30) is provided as outgoing data.

The refresh programming method involves the control circuitry 46 implementing memory cell refresh programming. Thus, control circuitry 46 may be loaded with software, i.e. non-transitory electronically readable instructions, or firmware, or can consist of respective circuits, or any combination thereof, to perform the methods described herein. Control circuitry 46 may be implemented by a microcontroller, dedicated circuitry, a processor, a general purpose processor running firmware or software, or a combination thereof. Control circuitry 46 can also work under the control of an off chip controller or control signals.

In operation, programming can be performed by applying the programming voltages in discrete pulses, with intervening read operations to verify the programming state between programming pulses (i.e., sequential programming). Specifically, after each program pulse, a program verify read operation may be performed to determine if the selected cells have reached their respective target program state (i.e., reached their target read current Irtarget or target threshold voltage associated with the target program state). If the determination is yes for any given memory cell, then a program inhibit voltage can be applied for that given memory cell so that subsequent program pulses for the other cells do not further program the given memory cell. For example, once a memory cell in a particular row is determined to have achieved its desired program state, a program inhibit voltage can be applied to the corresponding bit line to prevent further programming of that memory cell. Memory cells determined to have not reached their desired program states are programmed with additional program pulses (also referred to as a program retry pulse train), often with a step-up in program parameter(s). The program retry pulse train continues until all the memory cells in the row to be programmed have reached their target program states.

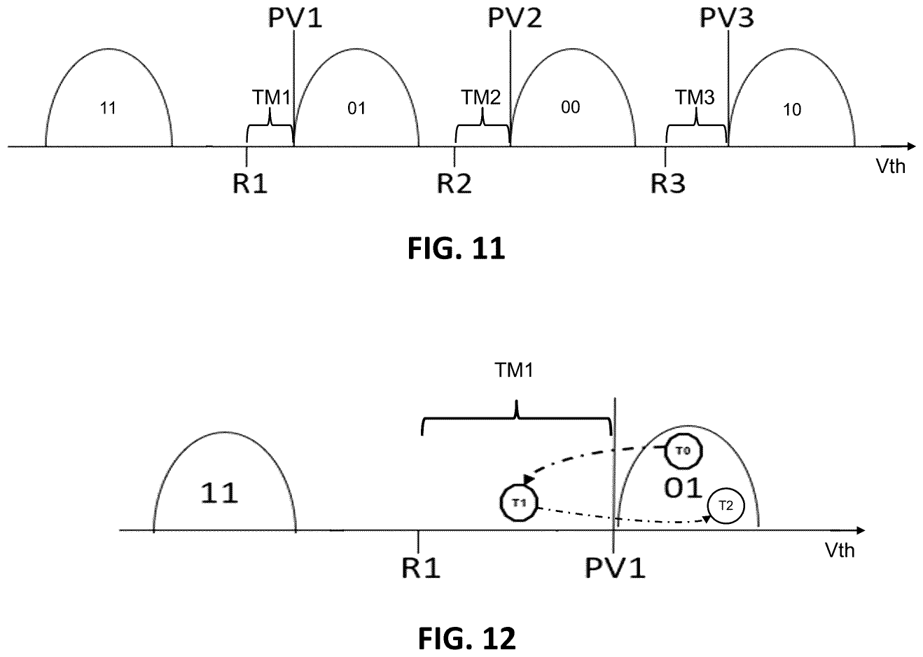

FIG. 11 is a diagram illustrating the program states of 2 bit (4 program states) memory cell as a function of threshold voltage Vth. The discussion going forward is directed to threshold voltage Vth and not also of read current Ir for simplicity, but the foregoing could be described in terms of read current Ir instead of threshold voltage Vth, as one is the inverse of the other (i.e., as threshold voltage Vth rises at higher program states, read current Ir falls, and vice versa). The fully erased state 11 corresponds to the distribution of lowest threshold voltages Vth for the fully erased memory cells. The first program state 01 corresponds to the distribution of next highest threshold voltages Vth for memory cells programmed to the program state 01. The second program state 00 corresponds to the distribution of next highest threshold voltages Vth for memory cells programmed to the program state 00. The third program state 10 corresponds to the distribution of next highest threshold voltages Vth for memory cells programmed to the program state 10. The respective distributions of threshold voltages Vth (as well as corresponding distributions of read currents Icell) for the respective program states can also be referred to as program state distributions.

Each of the program states 01, 00, 10 is associated with a program verify voltage PV, and a reference voltage R. The program verify voltage PV is used during sequential programing so that the distribution of threshold voltages Vth for a given program state is equal to or greater than the respective program verify voltage PV. The reference voltage R is used during subsequent read operations to determine that a memory cell is programmed in the respective program state. For instance, taking program state 01 as an example, sequential programming of memory cells to be programmed to the program state 01 continues until the threshold voltage Vth for all the memory cells meets or exceeds the program verify voltage PV1 (as shown by the threshold voltage Vth distribution for the program state 01 in FIG. 11). During subsequent read operations, memory cells having threshold voltages Vth greater than reference voltage R1 (but less than reference voltage R2 associated with the next highest program state 00) are determined to be in the program state 01.

The difference between the program verify voltage PV and the respective reference voltage R provides a target margin TM, to avoid read errors for memory cells that exhibit a minor downward drift of threshold voltage Vth due to charge loss. Taking program state 01 as an example, after memory cells targeted for program state 01 are programmed to threshold voltages Vth at or exceeding program verify voltage PV1, those memory cells can be accurately identified as program state 01 in subsequent read operations so long as any downward drift of their threshold voltages Vth due to charge loss does not extend beyond the target margin TM1 (i.e., so long as the threshold voltages Vth remain above reference voltage R1).

However, downward drift of the threshold voltage Vth for a memory cell due to charge loss can continue over time, to the point that the threshold voltage Vth drops below the respective reference voltage R, which may result in a read error. To address this issue, a refresh operation can be implemented to detect a memory cell with a threshold voltage Vth that has drifted into its respective target margin TM, and to implement refresh programming to increase the memory cell's threshold voltage Vth to meet or exceed its respective program verify voltage PV. The refresh operation includes a refresh read operation, and if needed, a refresh program operation.

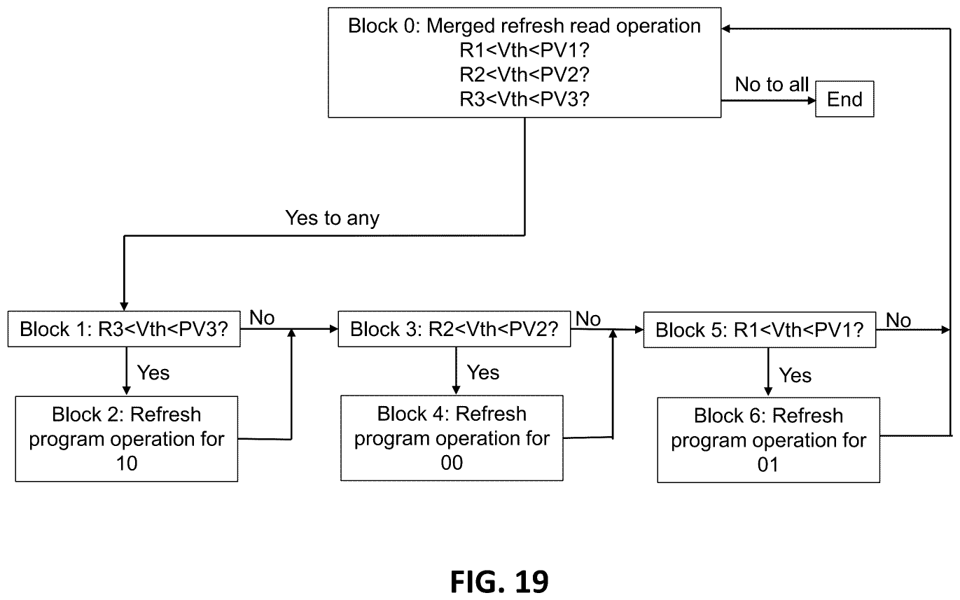

The refresh operation is illustrated in FIG. 12, using program state 01 as an example. The memory cells targeted for this program state are programmed with threshold voltages Vth equal to or above program verify voltage PV1. Taking one of those memory cells as an example (example memory cell), at time T0, the example memory cell has a threshold voltage Vth within the respective program state distribution for program state 01 (i.e., its threshold voltage Vth exceeds program verify voltage PV1 as graphically shown as “T0” in FIG. 12). Between time T0 and subsequent time T1, the threshold voltage Vth of the example memory cell has drifted down into the target margin TM1. At time T1, a refresh operation is performed that includes a refresh read operation to determine if the memory cells have drifted below the program verify voltage PV1. As shown in FIG. 12, at time T1, the example memory cell has a threshold voltage Vth below program verify voltage PV1 but above reference voltage R1 (i.e., in target margin TM1). In response to the refresh read operation determination of the example memory cell program state, a refresh program operation is performed at time T2 to program the example memory cell back into the respective program state distribution for program state 01 so that the example memory cell has a threshold voltage Vth equal to or above program verify voltage PV1. The refresh program operation can include just a single program pulse (which can include lower voltages than those used for the initial sequential programming pulses) designed to change the programming state of any memory cell in the target margin TM1 to within the program state distribution for program state 01 (i.e., a threshold voltage Vth equal to or above program verify voltage PV1). For many applications, it may be safe to assume that any memory cells in the target margin TM1 should be programmed back into the program state distribution having a threshold voltage Vth equal to or above the program verify voltage PV1. Memory cells programmed to the program state 01 but with threshold voltages Vth falling below reference voltage R1 would constitute an error, and can be handled by conventional error correction code (ECC) techniques that detect and correct memory cell programming that is deemed corrupt, or sector erase and reprogramming, or by the method described below with respect to FIGS. 19-21. Therefore, by performing the refresh operation after a memory cell has drifted into its respective target margin, but before it has drifted below its respective reference voltage R, ECC and/or sector erase/reprogramming can be avoided because the threshold voltage Vth of the memory cell is increased back equal to or above it respective program verify voltage PV after being properly identified as a memory cell that has suffered charge loss. The same refresh operation described above with respect to program state 01 can be performed for any other program states (e.g., program states 00 and 10 in the example of FIG. 11). The refresh operations for the various program states may be performed routinely when the memory device is not actively in use, to avoid delaying user operation of the device.

Higher reliability may be obtainable by sequentially performing refresh operations starting with the highest program state first, and then the next highest program state, and so on. The higher the program state, the higher the program voltages may be for refresh program operations, which in turn may result in program disturb of the program states for memory cells programmed at the lower program states. Therefore, in the example of FIG. 11, the refresh operation can begin by performing a refresh operation on the memory cells programmed at state 10 (e.g., refresh read operation to detect memory cells in target margin TM3, followed by refresh program operation for those detected memory cells back into the program state distribution for program state 10, specifically, threshold voltage Vth equal or above program verify voltage PV3), followed by a refresh operation on the memory cells programmed at program state 00 (e.g., refresh read operation to detect memory cells in target margin TM2, followed by refresh program operation for those detected memory cells back into the program state distribution for program state 00, specifically, threshold voltage Vth equal or above program verify voltage PV2), and so on.

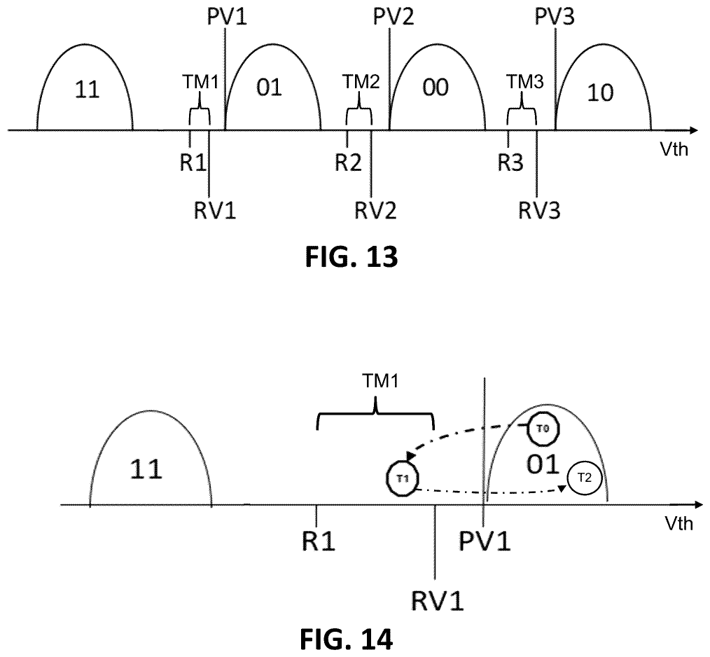

FIGS. 13 and 14 illustrate another example, where a refresh verify voltage RV is associated with each program state, where the refresh verify voltage RV is less than the respective program verify voltage PV but greater than the respective reference voltage R, and where the respective target margin TM includes threshold voltages Vth between the respective refresh verify voltage RV and the respective reference voltage R. Using the program state 01 as an example, the target margin TM1 includes threshold voltages Vth between reference voltage R1 and refresh verify voltage RV1. During a refresh operation, any memory cell previously programmed to program state 01 but found in a refresh read operation to have drifted into the target margin TM1 will undergo a refresh program operation to place the memory cell back within the program distribution equal to or above program verify voltage PV1. However, any memory cells found in a refresh read operation to have drifted to a threshold voltage Vth between refresh verify voltage RV1 and program verify voltage PV1 will not undergo a refresh program operation. By creating a gap between the target margin TM1 and the program verify voltage PV1, refresh programming of memory cells drifting only a relatively small amount below program verify voltage PV1 is avoided which has two advantages: it speeds up the refresh operation, and it lowers the chances of memory cells very close to the program verify voltage PV1 from being overprogrammed by the refresh program operation (which could widen the program distribution).

Read operations can be performed by comparing the read current Ir through the memory cell being read to a reference current source, such as a reference memory cell. For instance, in the example of FIGS. 11 and 12, there could be six reference current sources, each corresponding to the current associated with one of the six voltages of FIG. 11 (program verify voltages PV1, PV2, PV3, and reference voltages R1, R2, R3). For the program state 01, the refresh read operation can involve two read stages. The first read stage compares the memory cell read currents Ir to the reference current source for reference voltage R1. The second read stage compares the memory cell read currents Ir to the reference current source for program verify voltage PV1. Any memory cell having a corresponding threshold voltage Vth (as indicated by its read current Ir) exceeding the reference voltage R1 but not exceeding the program verify voltage PV1 would be then subjected to a refresh program operation to increase its threshold voltage Vth back into the distribution above the program verify voltage PV1. If the memory cell exhibits read currents Ir in both read stages that correspond to threshold voltages Vth above both reference voltage R1 and program verify voltage PV1, then no refresh programming is needed. The memory cells programed to program states 00 and 10 can be subjected to a similar refresh operation, each with two read stages. As stated above, it can be beneficial to start with the highest programming state 10, and then the next highest programming state 00, and so on.

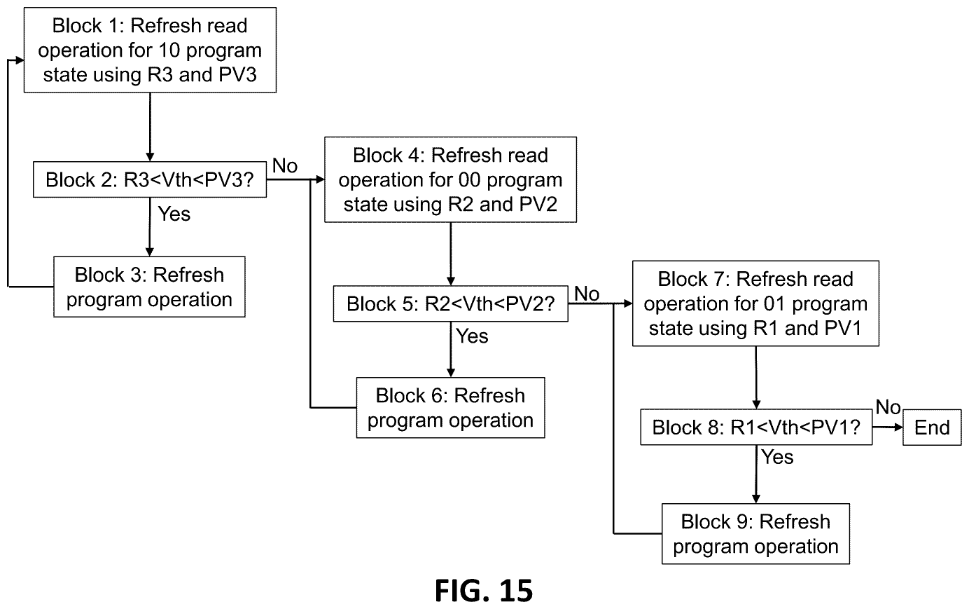

The process flow for the refresh operation described above with respect to FIGS. 11-12 is shown in FIG. 15. At Block 1, a refresh read operation is performed looking for memory cells in the 10 program state that have threshold voltages Vth which have drifted down into the target margin TM3 (i.e., having a threshold voltage Vth that is greater than reference voltage R3 but less than program verify voltage PV3). If any such memory cells are identified (i.e., yes at Block 2), then those memory cells are subjected to a refresh program operation (Block 3). The refresh read operation may be repeated (Block 1) until it is determined that no memory cells are in target margin TM3 (i.e., a no determination at Block 2). Then, a refresh read operation is performed (Block 4) looking for memory cells in the 00 program state that have threshold voltages Vth which have drifted down into the target margin TM2 (i.e., having a threshold voltage Vth that is greater than reference voltage R2 but less than program verify voltage PV2). If any such memory cells are identified (i.e., yes at Block 5), then those memory cells are subjected to a refresh program operation (Block 6). The refresh read operation may be repeated (Block 4) until it is determined that no memory cells are in target margin TM2 (i.e., a no determination at Block 5). Then, a refresh read operation is performed (Block 7) looking for memory cells in the 01 program state that have threshold voltages Vth which have drifted down into the target margin TM1 (i.e., having a threshold voltage Vth that is greater than reference voltage R1 but less than program verify voltage PV1). If any such memory cells are identified (i.e., yes at Block 8), then those memory cells are subjected to a refresh program operation (Block 9). The refresh read operation may be repeated (Block 7) until it is determined that no memory cells are in target margin TM1 (i.e., a no determination at Block 8).

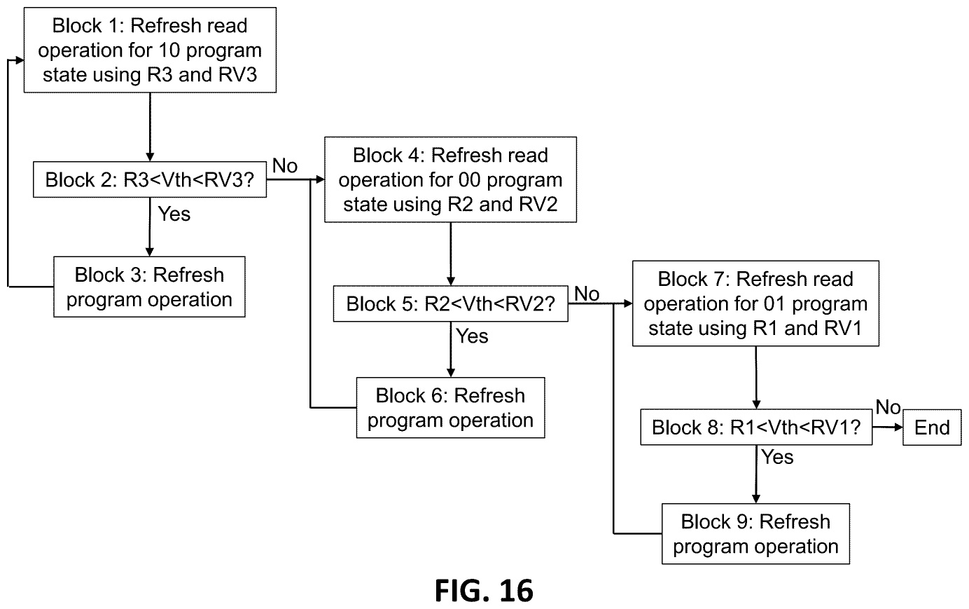

For the example of FIGS. 13 and 14, there can be nine reference current sources corresponding to the voltages PV1-PV3, R1-R3, and RV1-RV3. The three reference current sources corresponding to program verify voltages PV1-PV3 would be used during sequential programming of the memory cells to their respective program states. The three reference current sources corresponding to reference voltages R1-R3 would be used for normal use read operations and the first read stages of the refresh read operation. The three reference current sources corresponding to refresh verify voltages RV1-RV3 would be used for the second read stages of the refresh read operation. For any given refresh read operation of a given memory cell, if the memory cell read current corresponds to a threshold voltage Vth above the respective reference voltage R but not above the respective refresh verify voltage RV (i.e., the memory cell's threshold voltage is in the respective target margin TM), then refresh programming is implemented. If however the memory cell read current corresponds to a threshold voltage Vth above the respective reference voltage R and above the respective refresh verify voltage RV, then refresh programming is not implemented. The process flow for the refresh operation described above with respect to FIGS. 13-14 is shown in FIG. 16, which is the same as the process flow in FIG. 15 except Blocks 2, 5 and 8 use the respective refresh verify voltage instead of the respective program verify voltage PV for the upper end of the respective target margin TM.

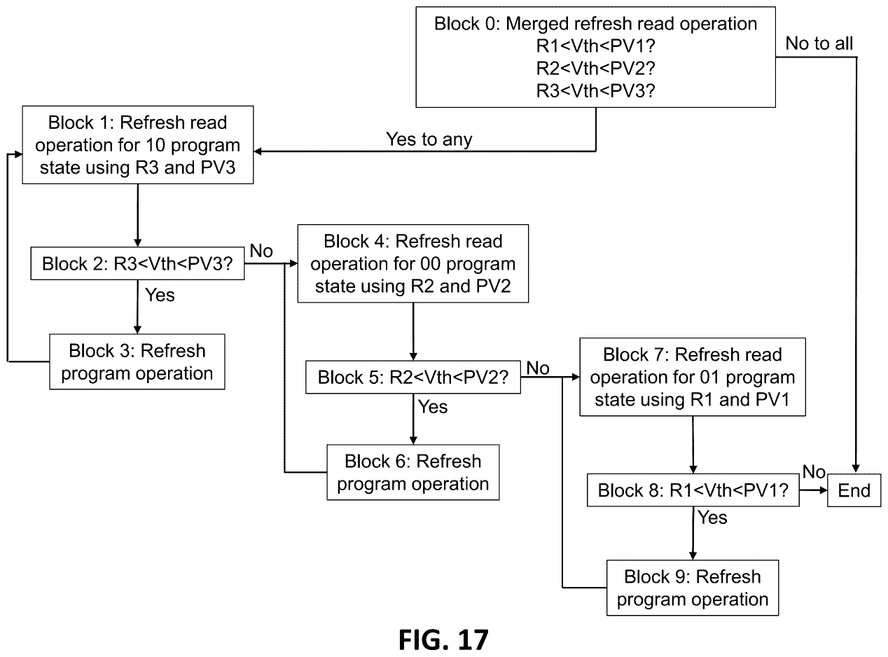

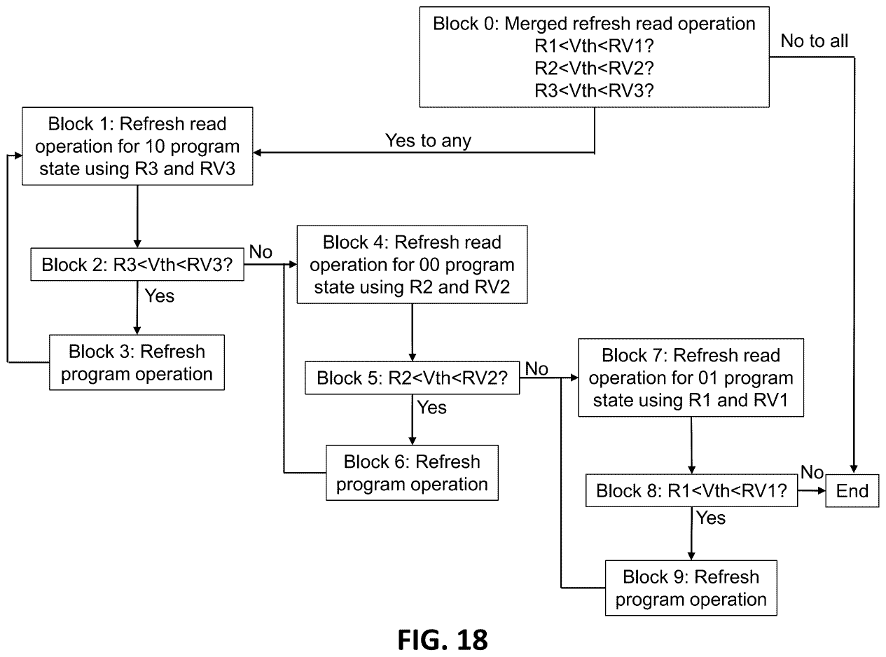

FIG. 17 is a process flow for another refresh operation example. In this example, the process flow begins by performing a merged refresh read operation, where in a first read stage at Block 0, the threshold voltages Vth corresponding to the read currents Ir of the memory cells being read are compared with reference voltages R1, R2 and R3. In a second read stage, the threshold voltages Vth corresponding to the read currents Ir of the memory cells being read are compared with the program verify voltages PV1, PV2 and PV3. If the threshold voltage Vth for any of the memory cells falls within any of the target margins TM1, TM2, TM3 (i.e., between reference voltage R1 and program verify voltage PV1, or between reference voltage R2 and program verify voltage PV2, or between reference voltage R3 and program verify voltage PV3), then there has been charge loss and the refresh operation of FIG. 15 (i.e. Blocks 1-9) is applied. If however none of the threshold voltages Vth for any of the memory cells falls between the respective reference voltage R and program verify voltage PV, then the refresh operation is terminated because there has not been any detected charge loss. The advantage of this example is if there has been no charge loss, then the refresh operation is relatively quick and avoids unnecessary read operations. It should be noted that this example can instead use refresh verify voltages RV1-RV3 and the refresh operation Blocks 1-9 of FIG. 16 instead of program verify voltage PV1-PV3 and the refresh operation Blocks of 1-9 of FIG. 15, as shown in FIG. 18.

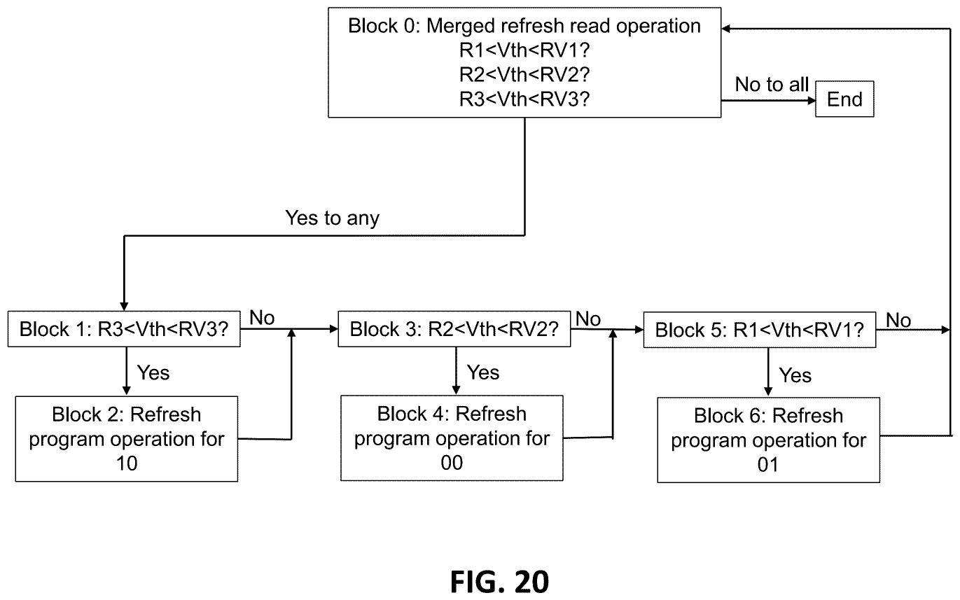

FIG. 19 is a process flow for another refresh operation example. In this example, the process flow begins by performing the merged refresh read operation and determination if the threshold voltage Vth for any of the memory cells falls with the respective target margin ranges TM as described above (i.e., between respective reference voltage R and respective program verify voltage PV) with respect to FIG. 17. If the answer is no to all, then the process ends. If the answer is yes to any, then the results of the comparisons can be saved (e.g., as XOR vectors), and later used in Blocks 1, 3, 5 for implementing refresh program operations as necessary (Blocks 2, 4, 6) for the various program states without performing refresh read operation for each program state. Once the refresh program operations are done, the merged refresh read operation can be conducted again to confirm no memory cells remain in their respective target margin TM. One advantage of this example is that the refresh read operations for memory cells programmed to different program states are performed together before the refresh program operations are performed, which can reduce the overall time needed for the refresh operation. FIG. 20 is a process flow for another refresh operation example, which is the same as that of FIG. 19, but respective refresh verify voltages RV are used instead of respective program verify voltages PV in Blocks 1, 3, 5, to determine if the respective refresh program operations are to be applied in Blocks 2, 4, 6.

As stated above, conventional ECC can be used for a memory cell that has suffered significant charge loss (i.e., so much charge loss that the threshold voltage Vth of the memory cell has drifted below its respective reference voltage R). Conventional ECC can determine that there is a read error for the affected memory cell, and can perform an erase operation followed by a program operation to program the memory cell back into its target distribution of threshold voltages (i.e., so that the threshold voltage Vth of the memory cell is at or above its respective program verify voltage PV). However, such conventional ECC reprogramming can be time consuming because most memory arrays are configured to erase entire sectors at once, so an entire sector of memory cells would have to be erased and reprogrammed in order to remedy the significant charge loss by as few as a single memory cell.

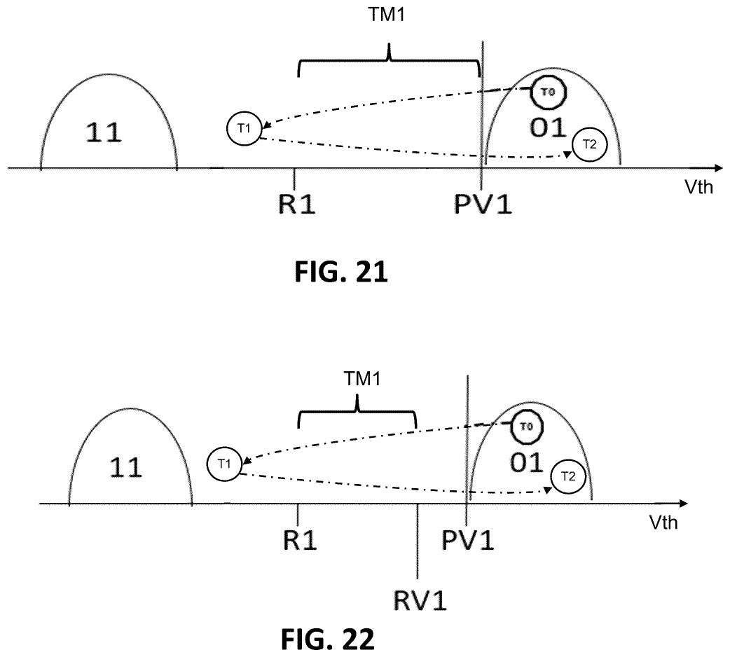

FIGS. 21-23 illustrate a method to address a problematic memory cell that has suffered significant charge loss since its last programming (i.e., it is significantly under-programmed). The method combines ECC with refresh programming to correct the program state of the under-programmed memory cell without having to erase any memory cells. FIGS. 21 and 22 correspond to the same examples as FIGS. 12 and 14 (i.e., a memory cell initially programmed to the program state 01 at time TO). However, at time T1, the threshold voltage Vth of the problematic memory cell has drifted below the reference voltage R1, so that during a read operation, the problematic memory cell is read to be at the program state 11 instead of the program state 01 (i.e., it is under-programmed at time T1). An ECC engine can be included as part of control circuitry 46, and can analyze the read results of groups of memory cells, and can determine from the word or message stored in those memory cells that there is an error in the read results from one or more memory cells (i.e., the ECC engine can identify the problematic memory cell of FIGS. 21 and 22 as being under programmed). Once that identification is made, refresh programming can be used to increase the threshold voltage Vth of the problematic memory cell back to its original program state (i.e., so that its threshold voltage Vth is at or above program verify voltage PV1 at time T2).

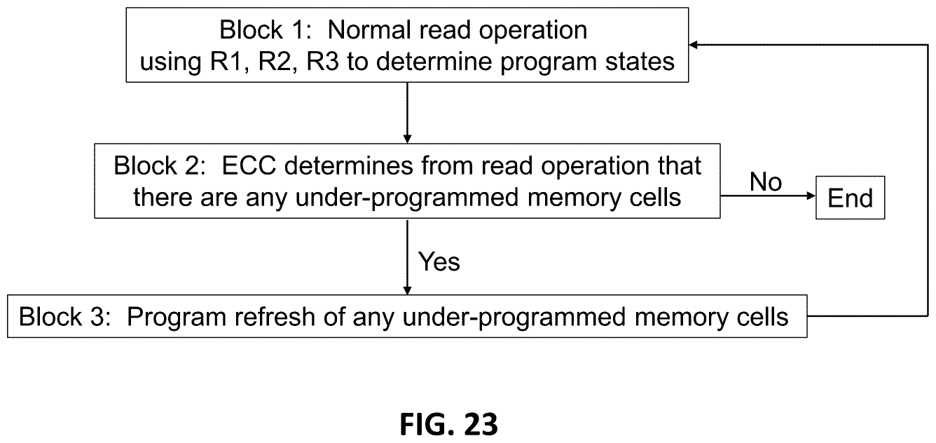

FIG. 23 illustrates the process flow of the method combining ECC and refresh programming. Using the above examples of memory cells having four possible program states, a normal read operation is performed at Block 1 using reference voltages R1, R2, R3 to determine the program states of the various memory cells (either 11, 01, 00, or 10). ECC is used at Block 2 to determine from the read operation if there are any under-programmed memory cells (i.e., memory cells that should be read at one program state but are reading at a lower program state, which can be the result of significant charge loss). If the determination is no, then the process ends. If the determination is yes, then program refresh is performed at Block 3 on the under-programmed memory cell(s) to increase their threshold voltages back to their respective original program states. Optionally, ECC can be used to identify a memory cell that has a threshold voltage that has drifted down beyond the next lowest program state (e.g., the memory cell is reading at a program state that is two or more program states lower than its original program state), and the program refresh operation can take that into account to use higher program voltages and/or more program pulses to more quickly program such a memory cell up the two more program states back to its original program state.

Charge loss can be addressed even in the case where some memory cells in the semiconductor device have threshold voltages Vth that have drifted into their respective target margins TM, while other memory cells of the semiconductor device that have threshold voltages Vth that have drifted below their respective reference voltages R. For example, a first refresh operation can be performed using the methods described above with respect to FIGS. 11-20 to perform a refresh program operation on the memory cells having threshold voltages Vth that have drifted into their respective target margins TM, and a second refresh operation can be performed using the method described above with respect to FIGS. 21-23 to perform a refresh program operation on the memory cells having threshold voltages Vth that have drifted below their respective reference voltages R.

While the above examples are described with respect to features that relate to memory cell voltages, it is to be understood that all such features equally relate to memory cell current, because each of the above described memory cell voltages has a corresponding memory cell current. For example, programming a memory cell so that its threshold voltage Vth meets or exceeds a program verify voltage PV necessarily means that the memory cell is being programmed so that its read current Ir meets or is below a program verify current that corresponds to the program verify voltage PV. Similarly, performing a user read operation on a memory cell to determine if its threshold voltage meets or exceeds a reference voltage R necessarily means that the memory cell is being read to determine if its read current Ir meets or is below a reference current that corresponds to the reference voltage R (i.e., doing one effectively does the other). The target margin TM for threshold voltages Vth between a reference voltage R and a program verify voltage PV corresponds to read currents Ir between a reference current (that corresponds to reference voltage R) and a program verify current (that corresponds to program verify voltage PV). Finally, refresh verify voltage RV for defining an upper end of a target margin TM with respect to threshold voltage Vth corresponds to a refresh verify current for defining a lower end of the target margin with respect to read current Ir. Therefore, the above described methods implemented with respect to the above described memory cell voltages are equally practiced with respect to corresponding memory cell currents irrespective of whether memory cell currents are converted to voltages to perform the determinations.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit any claims. While the examples described herein include memory cells operating with four possible program states (one of which is the erased state), fewer or greater than four program states can be used. Finally, the claims are comprising claims unless otherwise stated, and therefore “each” of a plurality of elements having a limitation does not preclude the inclusion of additional such elements lacking the limitation unless otherwise specifically claimed. It should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry.

What is claimed is:

1. A programming method for a semiconductor device, comprising:
programming a first memory cell to a first program state that is associated with a first program verify voltage and a first reference voltage such that the first memory cell has a first threshold voltage that meets or exceeds the first program verify voltage, wherein the first program verify voltage is greater than the first reference voltage;
determining in a first read operation that the first threshold voltage of the first memory cell has drifted down to between the first program verify voltage and the first reference voltage; and
in response to the determining in the first read operation, programming the first memory cell to increase the first threshold voltage of the first memory cell to meet or exceed the first program verify voltage.

2. The method of claim 1, comprising:
determining the first memory cell is programmed to the first program state by performing a second read operation to determine the first threshold voltage of the first memory cell meets or exceeds the first reference voltage.

3. The method of claim 1, wherein the determining in the first read operation comprises determining that the first threshold voltage of the first memory cell has drifted down to between a first refresh verify voltage and the first reference voltage, wherein the first refresh verify voltage is less than the first program verify voltage.

4. The method of claim 1, comprising:
programming a second memory cell to a second program state that is associated with a second program verify voltage and a second reference voltage such that the second memory cell has a second threshold voltage that meets or exceeds the second program verify voltage and that is less than the first reference voltage, wherein the second program verify voltage is greater than the second reference voltage, and wherein the second program verify voltage and the second reference voltage are less than the first reference voltage;
determining in a second read operation that the second threshold voltage of the second memory cell has drifted down to between the second program verify voltage and the second reference voltage; and
in response to the determining in the second read operation, programming the second memory cell to increase the second threshold voltage of the second memory cell to meet or exceed the second program verify voltage.

5. The method of claim 4, wherein the programming of the first memory cell in response to the determining in the first read operation is performed before the programming of the second memory cell in response to the determining in the second read operation.

6. The method of claim 4, comprising:
determining the second memory cell is programmed to the second program state by performing a third read operation to determine the second threshold voltage of the second memory cell meets or exceeds the second reference voltage and is lower than the first reference voltage.

7. The method of claim 4, wherein the determining in the second read operation comprises determining that the second threshold voltage of the second memory cell has drifted down to between a second refresh verify voltage and the second reference voltage, wherein the second refresh verify voltage is less than the second program verify voltage.

8. The method of claim 4, wherein the first and second read operations are performed before the programming of the first memory cell in response to the determining in the first read operation and the programming of the second memory cell in response to the determining in the second read operation.

9. The method of claim 1, comprising:
programming a second memory cell to a second program state that is associated with a second program verify voltage and a second reference voltage such that the second memory cell has a second threshold voltage that meets or exceeds the second program verify voltage, wherein the second program verify voltage is greater than the second reference voltage, and wherein the second program verify voltage and the second reference voltage are greater than the first reference voltage and the first program verify voltage;
determining in a second read operation that the second threshold voltage of the second memory cell has drifted down to between the first reference voltage and the second reference voltage; and
in response to the determining in the second read operation, programming the second memory cell to increase the second threshold voltage of the second memory cell to meet or exceed the second program verify voltage.

10. A semiconductor device, comprising:
a plurality of memory cells formed on a semiconductor substrate; and control circuitry to:
program a first memory cell of the plurality of memory cells to a first program state that is associated with a first program verify voltage and a first reference voltage such that the first memory cell has a first threshold voltage that meets or exceeds the first program verify voltage, wherein the first program verify voltage is greater than the first reference voltage;
determine in a first read operation that the first threshold voltage of the first memory cell has drifted down to between the first program verify voltage and the first reference voltage; and
in response to the determination in the first read operation, program the first memory cell to increase the first threshold voltage of the first memory cell to meet or exceed the first program verify voltage.

11. The semiconductor device of claim 10, wherein the control circuitry to:
determine the first memory cell is programmed to the first program state in a second read operation to determine the first threshold voltage of the first memory cell meets or exceeds the first reference voltage.

12. The semiconductor device of claim 10, wherein the determination in the first read operation comprises determine that the first threshold voltage of the first memory cell has drifted down to between a first refresh verify voltage and the first reference voltage, wherein the first refresh verify voltage is less than the first program verify voltage.

13. The semiconductor device of claim 10, wherein the control circuitry to:
program a second memory cell of the plurality of memory cells to a second program state that is associated with a second program verify voltage and a second reference voltage such that the second memory cell has a second threshold voltage that meets or exceeds the second program verify voltage and that is less than the first reference voltage, wherein the second program verify voltage is greater than the second reference voltage, and wherein the second program verify voltage and the second reference voltage are less than the first reference voltage;
determine in a second read operation that the second threshold voltage of the second memory cell has drifted down to between the second program verify voltage and the second reference voltage; and
in response to the determination in the second read operation, program the second memory cell to increase the second threshold voltage of the second memory cell to meet or exceed the second program verify voltage.

14. The semiconductor device of claim 13, wherein the program of the first memory cell in response to the determination in the first read operation is performed before the program of the second memory cell in response to the determination in the second read operation.

15. The semiconductor device of claim 13, wherein the control circuitry to:
determine the second memory cell is programmed to the second program state in a third read operation to determine the second threshold voltage of the second memory cell meets or exceeds the second reference voltage and is lower than the first reference voltage.

16. The semiconductor device of claim 13, wherein the determination in the second read operation comprises determine that the second threshold voltage of the second memory cell has drifted down to between a second refresh verify voltage and the second reference voltage, wherein the second refresh verify voltage is less than the second program verify voltage.

17. The semiconductor device of claim 13, wherein the first and second read operations are performed before the program of the first memory cell in response to the determination in the first read operation and the program of the second memory cell in response to the determination in the second read operation.

18. The semiconductor device of claim 10, wherein the control circuitry to:
program a second memory cell of the plurality of memory cells to a second program state that is associated with a second program verify voltage and a second reference voltage such that the second memory cell has a second threshold voltage that meets or exceeds the second program verify voltage, wherein the second program verify voltage is greater than the second reference voltage, and wherein the second program verify voltage and the second reference voltage are greater than the first reference voltage and the first program verify voltage;
determine in a second read operation that the second threshold voltage of the second memory cell has drifted down to between the first reference voltage and the second reference voltage; and
in response to the determination in the second read operation, program the second memory cell to increase the second threshold voltage of the second memory cell to meet or exceed the second program verify voltage.

19. The semiconductor device of claim 10, wherein each of the plurality of memory cells comprises:
a source region and a drain region formed in the semiconductor substrate, with a channel region of the semiconductor substrate extending between the source region and the drain region; and
a floating gate disposed over, for controlling a conductivity of, a first portion of the channel region.

20. The semiconductor device of claim 19, wherein each of the plurality of memory cells comprises:
a select gate disposed over, for controlling a conductivity of, a second portion of the channel region.

21. The semiconductor device of claim 20, wherein each of the plurality of memory cells comprises:
an erase gate disposed over the source region.

22. The semiconductor device of claim 21, wherein each of the plurality of memory cells comprises:
a control gate disposed over the floating gate.
